(19) United States
(12) Patent Application Publication
(10) Pub. No.: US 2023/0398563 A1
(43) Pub. Date: Dec. 14, 2023

(54) PARALLEL-TYPE COATING APPARATUS AND METHOD FOR COATING MULTILAYER FILM

(71) Applicant: LINCO TECHNOLOGY CO., LTD., Taichung City (TW)

(72) Inventors: Yi-Yuan HUANG, Taichung City (TW); Yi-Cheng LIU, Taichung City (TW)

(73) Assignee: LINCO TECHNOLOGY CO., LTD., Taichung City (TW)

(21) Appl. No.: 18/074,263

(22) Filed: Dec. 2, 2022

(30) Foreign Application Priority Data
Jun. 8, 2022 (TW) 111121270

(51) Int. Cl. B05B 13/02; B05D 3/04; B05D 3/02; B05D 3/00

(52) U.S. Cl. CPC B05B 13/0235; B05D 3/0493; B05D 3/0218; B05D 3/007

(57) ABSTRACT

A parallel-type coating apparatus for coating at least one object to be coated carried by a carrier includes a double-layer vacuum chamber having feed and discharge chambers opposite to each other in a Z-direction, and a plurality of process chambers for performing at least a fixed point coating on the at least one object to be coated. The double-layer vacuum chamber and the process chambers are arranged in two juxtaposed rows in a Y-direction transverse to the Z-direction. A feed lifting mechanism is disposed in one of the double-layer vacuum chamber 3 and the process chambers, and includes a feed lifting seat movable in the Z-direction. A plurality of first conveying devices are respectively disposed in the other ones of the process chambers for conveying the carrier. A method for coating a multilayer film on at least one object to be coated carried by a carrier is also disclosed.

### CROSS-REFERENCE TO RELATED APPLICATION

This application claims priority to Taiwanese Invention Patent Application No. 111121270, filed on Jun. 8, 2022.

### FIELD

The disclosure relates to a parallel-type coating apparatus and a method for coating a multilayer film.

### BACKGROUND

Referring to FIG. 1, an existing continuous coating production line includes a load-in chamber 11, a load-out chamber 12 opposite to the load-in chamber 11, a plurality of coating areas 13 between the load-in and load-out chambers 11, 12, a plurality of buffer areas 14 arranged such that each coating area 13 is disposed between two buffer areas 14, and an automatic return unit 15. Through a plurality of carriers 16 that carry a plurality of substrates (not shown) from the load-in chamber 11 toward the load-out chamber 12 after passing through the coating areas 13 and after moving back and forth in the adjacent buffer areas 14, a multilayer film can be formed on each substrate. Further, after the substrates are discharged from the load-out chamber 12, the carriers 16 are returned one by one to the load-in chamber 11 through the automatic return unit 15. Thus, the existing continuous coating production line has a high speed production and a high yield.

However, in the existing continuous coating production line, it is necessary to dispose two buffer areas 14 on opposite sides of each coating area 13 to regulate the timing of the carriers 16 entering each coating area 13, so the equipment used for the existing continuous coating production line is long and occupies a large floor area. Furthermore, the existing continuous coating production line includes the buffer areas 14 and the automatic return unit 15, and requires a large number of the carriers 16 to maintain the continuous production, thereby causing increase in the production and operating costs thereof.

### SUMMARY

Therefore, an object of the present disclosure is to provide a parallel-type coating apparatus that can alleviate at least one of the drawbacks of the prior art.

Accordingly, a parallel-type coating apparatus of this disclosure is suitable for coating at least one object to be coated carried by a carrier, and includes a double-layer vacuum chamber, a plurality of process chambers, a feed lifting mechanism, and a plurality of first conveying devices.

The double-layer vacuum chamber includes a feed chamber and a discharge chamber opposite to each other in a Z-direction. The feed chamber is configured for feeding the carrier. The discharge chamber is configured for discharging the carrier, The process chambers are provided for performing at least a fixed point coating on the at least one object to be coated. Two of the process chambers are immediately adjacent to the double-layer vacuum chamber. The double-layer vacuum chamber and the process chambers are arranged in two juxtaposed rows in a Y-direction transverse to the Z-direction.

The feed lifting mechanism is disposed in one of the double-layer vacuum chamber 3 and the process chambers, and includes a feed lifting seat for carrying the carrier. The feed lifting seat is movable in the Z-direction, and includes a first transfer device for conveying the carrier to move in an X-direction transverse to the Y-direction and the Z-direction, and a second transfer device for conveying the carrier to move in the Y-direction. The first conveying devices are respectively disposed in the other ones of the process chambers for conveying the carrier to move in the X-direction or Y-direction.

Another object of this disclosure is to provide a method for coating a multilayer film that can alleviate at least one of the drawbacks of the prior art.

Accordingly, a method for coating a multilayer film on at least one object to be coated carried by a carrier, comprising:
(A) feeding the carrier carrying the at least one object to be coated into a feed chamber of a double-layer vacuum chamber;
(B) driving the carrier to pass through a plurality of process chambers arranged in two juxtaposed rows so as to form the at least one object to be coated into at least one coated object with a multilayer film; and
(C) driving the carrier together with the at least one coated object to discharge from a discharge chamber of the double-layer vacuum chamber which is opposite to the feed chamber in a Z-direction.

### BRIEF DESCRIPTION OF THE DRAWINGS

Other features and advantages of the disclosure will become apparent in the following detailed description of the embodiments with reference to the accompanying drawings. It is noted that various features may not be drawn to scale.

FIG. 1 is a schematic view of an existing continuous coating production line.

FIG. 2 is a perspective view of a parallel-type coating apparatus according to the first embodiment of the present disclosure.

FIG. 3 is a sectional schematic view illustrating how a carrier is fed into a feed chamber of the first embodiment.

FIG. 4 is a schematic top view of the first embodiment.

FIG. 5 is a perspective view of a feed lifting mechanism of the first embodiment.

FIG. 6 is another schematic top view of the first embodiment.

FIGS. 7A and 7B are flow charts, illustrating the steps involved in a method for coating a multilayer film using the first embodiment.

FIG. 8 is a view similar to FIG. 3, but illustrating how the carrier is discharged from a discharge chamber of the first embodiment.

FIG. 9 is a schematic view illustrating each of first to third coating chambers of the first embodiment being provided with a cooling device.

FIG. 10 is a view similar to FIG. 6, but illustrating an alternative form of the first embodiment.

FIG. 11 is a view similar to FIG. 6, but illustrating another alternative form of the first embodiment.

FIG. 12 is a schematic top view of a parallel-type coating apparatus according to the second embodiment of this disclosure.

FIG. 13 is a schematic top view of a parallel-type coating apparatus according to the third embodiment of this disclosure.

FIG. 14 is a schematic top view of a parallel-type coating apparatus according to the fourth embodiment of this disclosure.

FIG. 15 is a sectional schematic view illustrating a feed lifting mechanism disposed in a double-layer vacuum chamber of this disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

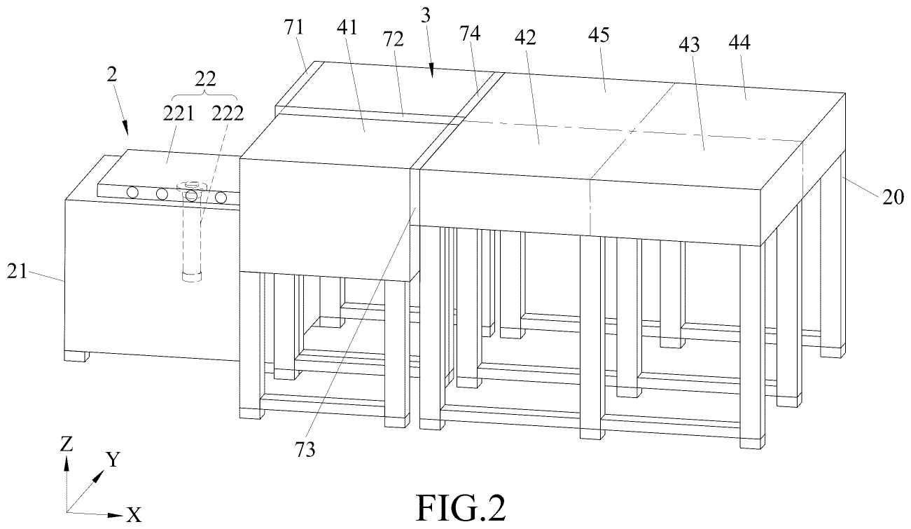

In the description below, based on the orientation shown in FIG. 2, the X-direction is a direction that runs leftward and rightward, the Y-direction is a direction that runs forward and rearward transverse to the X-direction, and the Z-direction is a direction that runs upward and downward transverse to the X direction and the Y-direction.

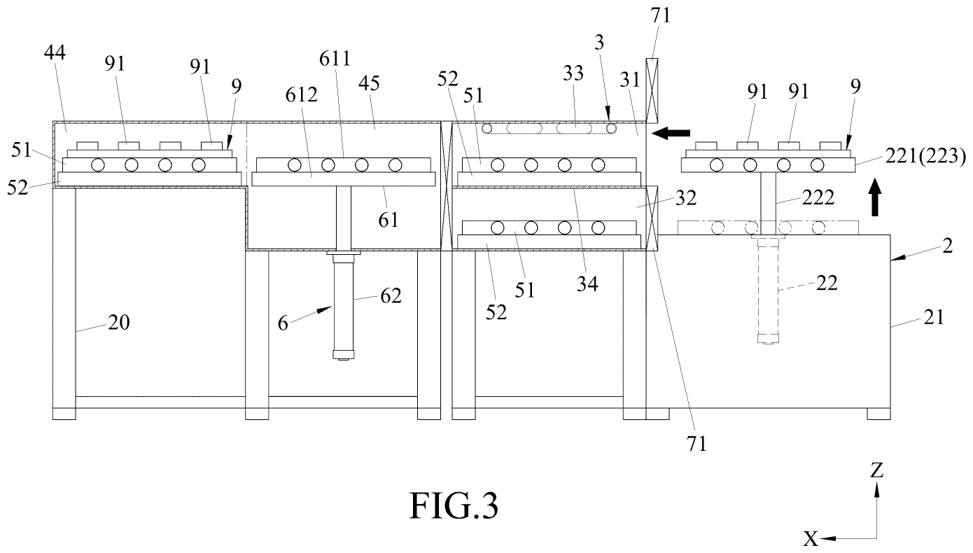

Referring to FIGS. 2 to 4, a parallel-type coating apparatus according to the first embodiment of the present disclosure is suitable for coating a plurality of objects to be coated 91 carried by a plurality of carriers 9. As shown in FIG. 3, each carrier 9 carries four objects to be coated 91, but is not limited thereto. Each object to be coated 91 may be a wafer, a chip, a semiconductor material, a substrate, a semiconductor packaged semi-finished product, a semiconductor packaged finished product, a plastic product, etc., and is not limited thereto, as long as coating can be applied on the object. In this embodiment, the objects to be coated 91 are packaged finished products. The parallel-type coating apparatus of this embodiment includes a loading and unloading area 2, a double-layer vacuum chamber 3, a treatment chamber 41, a first coating chamber 42, a second coating chamber 43, a third coating chamber 44, a buffer chamber 45, a plurality of first conveying devices 51, a plurality of second conveying devices 52, and a feed lifting mechanism 6. In this embodiment, the treatment chamber 41, the first to third coating chambers 42 to 44, and the buffer chamber 45 are process chambers for performing a fixed point coating on each object to be coated 91. The double-layer vacuum chamber 3 and the process chambers 41 to 45 are disposed on a top side of a hollow frame 20. The hollow design of the hollow frame 20 facilitates the installation configuration of vacuum pumps and other devices.

The loading and unloading area 2 includes a fixed seat 21 and a loading lifting mechanism 22 mounted on the fixed seat 21. The loading lifting mechanism 22 includes a loading lifting seat 221, and a loading drive unit 222 for driving the loading lifting seat 221 to move up and down in the Z-direction. The loading lifting seat 221 is configured for placement of each carrier 9 thereon, and has a loading conveying device 223 for conveying each carrier 9 to move in the X-direction. In this embodiment, the loading conveying device 223 is a horizontal conveying system. Since the horizontal conveying system of the coating apparatus is an existing technology and has many variations, and since those with ordinary skill in the art can infer the extended details from the above description, a detailed description thereof is omitted herein.

The double-layer vacuum chamber 3 is immediately adjacent to the loading and unloading area 2 in the X-direction, and includes a partition plate 34, a heating device 33, and two vacuum valves 71. The partition plate 34 divides the double-layer vacuum chamber 3 into a feed chamber 31 and a discharge chamber 32 which are independent airtight compartments and which are opposite to each other in the Z-direction. The feed chamber 31 is disposed above the discharge chamber 32. The vacuum degree of each of the feed chamber 31 and the discharge chamber 32 of this embodiment ranges from 10⁻¹ to 10⁻² Torr, but in some embodiments, the vacuum degree of each of the feed chamber 31 and the discharge chamber 32 may range from atmospheric pressure to 10⁻⁶ Torr. The vacuum degree is determined according to the operation requirements, and the degrees of vacuum of the feed chamber 31 and the discharge chamber 32 are not necessarily the same, but can be set separately.

The heating device 33 is mounted inside the feed chamber 31 for heating and baking the objects to be coated 91 to remove moisture therefrom. However, in other variations where baking is not required, the heating device 33 may be omitted. The vacuum valves 71 are respectively disposed on the feed chamber 31 and the discharge chamber 32 for isolating the double-layer vacuum chamber 3 from the atmospheric environment to maintain its degree of vacuum.

The treatment chamber 41 is immediately connected to the double-layer vacuum chamber 3 in the Y-direction. The first coating chamber 42 is connected to the treatment chamber 41 in the X-direction. The second coating chamber 43 is connected to the first coating chamber 42 in the X-direction. The third coating chamber 44 is connected to the second coating chamber 43 in the Y-direction. The buffer chamber 45 is connected to the first coating chamber 42 in the Y-direction, and is connected between the third coating chamber 44 and the double-layer vacuum chamber 3 in the X-direction. With the double-layer vacuum chamber 3, the treatment chamber 41, the first to third coating chambers 42 to 44, and the buffer chamber 45 being arranged in two juxtaposed rows in the Y-direction, the length of the coating apparatus of this disclosure in the X-direction can be shortened. The feed chamber 31, the treatment chamber 41, and the first to third coating chambers 42 to 44 have the same height in the Z-direction. The buffer chamber 45 has a height the same as that of the double-layer vacuum chamber 3.

A vacuum valve 72 is disposed between the treatment chamber 41 and the double-layer vacuum chamber 3. The treatment chamber 41 is used for pre-treatment of the objects to be coated 91, such as, but not limited to, plasma cleaning, plasma activation and surface modification, plasma etching, etc. Plasma cleaning can remove the surface contamination of the objects to be coated 91 and clean the metal surface or conductive ground pad, etc. Plasma activation can change the physical or chemical properties of the objects to be coated 91, which helps to improve the bondability of subsequent coatings. The vacuum degree of the treatment chamber 41 of this embodiment ranges from 10⁻¹ to 10⁻³ Torr, but may also have different ranges according to the structural characteristics, material types or operation requirement of the objects to be coated 91, for example, 10⁻² to 10⁻³ Torr or 10⁻¹ to 10^{31 2} Torr.

The first to third coating chambers 42 to 44 and the buffer chamber share a same vacuum chamber, communicate with each other, and have the same vacuum degree which is not lower than that of the treatment chamber 41. In this embodiment, the vacuum degree of each of the first to third coating chambers 42 to 44 and the buffer chamber 45 is 10⁻³ Torr. With the chambers being arranged from a low to a high degree of vacuum, the vacuuming time of each chamber can be shortened, and the efficiency of evacuation can be optimized to shorten the production cycle, thereby increasing the productivity and reducing the manufacturing cost of this disclosure.

The first conveying devices 51 are respectively disposed in the feed chamber 31, the discharge chamber 32, the treatment chamber 41, and the first to third coating chambers 42 to 44 for conveying the carrier 9 to move in the X- or Y-direction. The second conveying devices 52 are respectively located on bottom sides of the first conveying devices 51 for respectively driving the first conveying devices 51 to rotate 90 degrees. The first and second conveying devices 51, 52 respectively adopt the principle of a horizontal conveying system and a rotary table to achieve the function of conveying the carrier 9 in the X-direction and the Y-direction. Through these configurations, the carrier 9 can move among the feed chamber 31, the discharge chamber 32, the treatment chamber 41, and the first to third coating chambers 42 to 44.

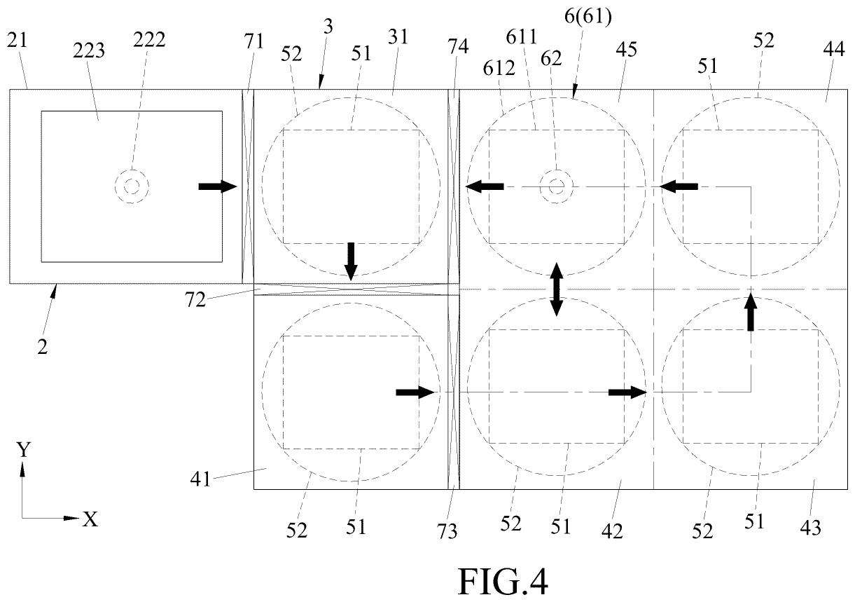

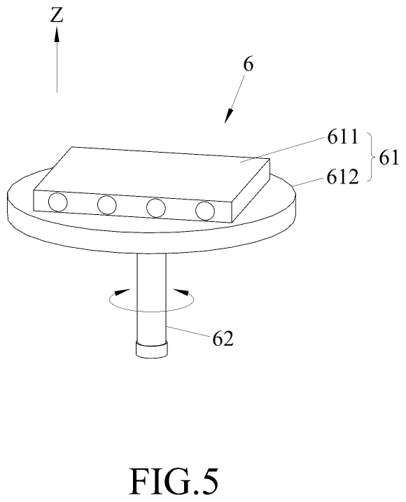

Referring to FIG. 5, in combination with FIGS. 3 and 4, the feed lifting mechanism 6 is disposed in the buffer chamber 45, and includes a feed lifting seat 61 for carrying the carrier 9, and a feed drive unit 62 for driving the feed lifting seat 61 to move up and down in the Z-direction. The carrier 9 moves up and down along with the feed lifting seat 61 when the latter is driven by the feed drive unit 62. In this embodiment, the feed drive unit 62 is an electric cylinder, but is not limited thereto. In other embodiments, the feed drive unit 62 may be a pneumatic cylinder, a linear motor, a lead screw or other transmission mechanism that can drive the feed lifting seat 61 to move up and down in the Z-direction. The feed lifting seat 61 includes a first transfer device 611 for conveying the carrier 9 to move in the X- or Y-direction, and a second transfer device 612. In this embodiment, the first transfer device 611 is an existing horizontal conveying system, and the second transfer device 612 is a rotary table which can drive the feed lifting seat 61 to rotate 90 degrees, after which the carrier 9 is conveyed to move in the Y- or X-direction by the first transfer device 611. In other variations, the second transfer device 612 may also adopt the existing horizontal conveying system or other conveying mechanism.

A vacuum valve 73 is disposed between the first coating chamber 42 and the treatment chamber 41, and a vacuum valve 74 is disposed between the buffer chamber 45 and the double-layer vacuum chamber 3 to maintain the degree of vacuum in each chamber.

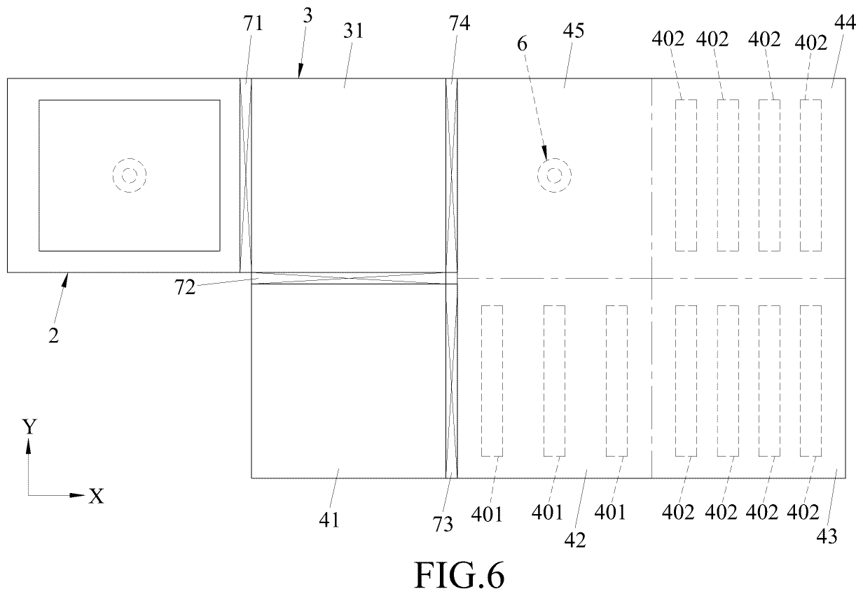

Referring to FIG. 6, a plurality of stainless steel targets 401 are disposed in the first coating chamber 42, while a plurality of copper (Cu) targets 402 are disposed in each of the second and third coating chambers 43 and 44. In this embodiment, each of the targets 401, 402 is a cylindrical target (i.e., a rotating target). By optimizing a sputtering angle of a magnet bar inside the cylindrical target, surfaces (including a top surface and a side surface) of the objects to be coated 91 (see FIG. 3) can be uniformly sputtered. However, in other variations, each of the first to third coating chambers 42 to 44 may be provided with a single cylindrical target, a single large flat target, a single large circular target or a plurality of flat targets. The material and quantity of the targets 401, 402 are selected according to the requirements of the coating, and by optimizing the sputtering angle of the target 401, 402, the angle of oscillation of the magnet bar, the coating power, and other parameters, the uniformity of film thickness can be improved, so that high and low peaks in the coating can be prevented.

The buffer chamber 45 is not provided with any target 401, 402, but serves as a buffer zone for temporarily storing the carriers 9 (see FIG. 3). For example, but not limited to, when sputtering a three-layer film which consists of 0.03 to 0.1 μm stainless steel, 3 to 7 μm copper, and 0.3 to 0.8 μm stainless steel, the buffer chamber 45 can be used to regulate the time sequence of the carriers 9 entering and exiting each process chamber, and at the same time, can also control the objects to be coated 91 to enter and exit the first coating chamber 42 twice, so that a process chamber and a set of stainless steel targets 401 can be saved. It should be noted that, since the first to third coating chambers 42 to 44 and the buffer chamber 45 are located in the same vacuum chamber, to prevent the targets 401, 402 of each process chamber from sputtering to adjacent process chambers, a shield member may be disposed between each two adjacent process chambers. The material, number and size of the shield member may be selected according to actual requirements.

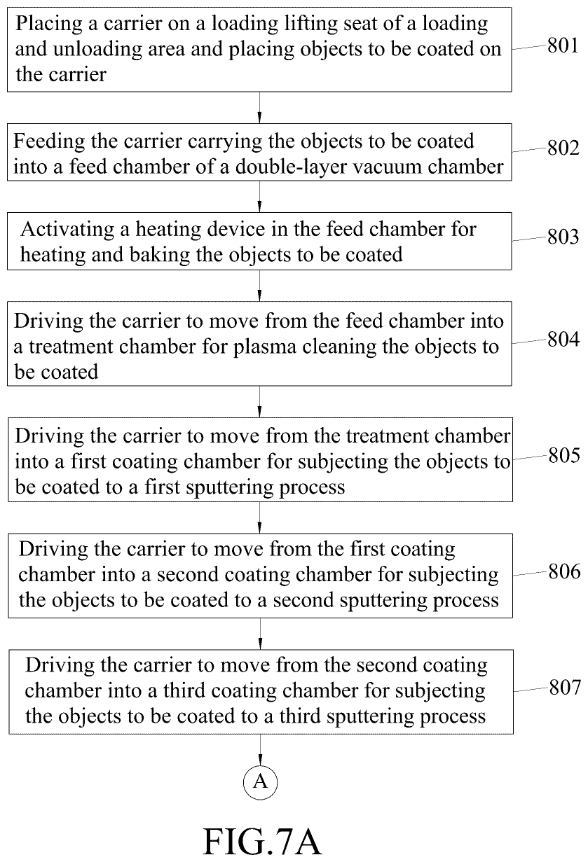

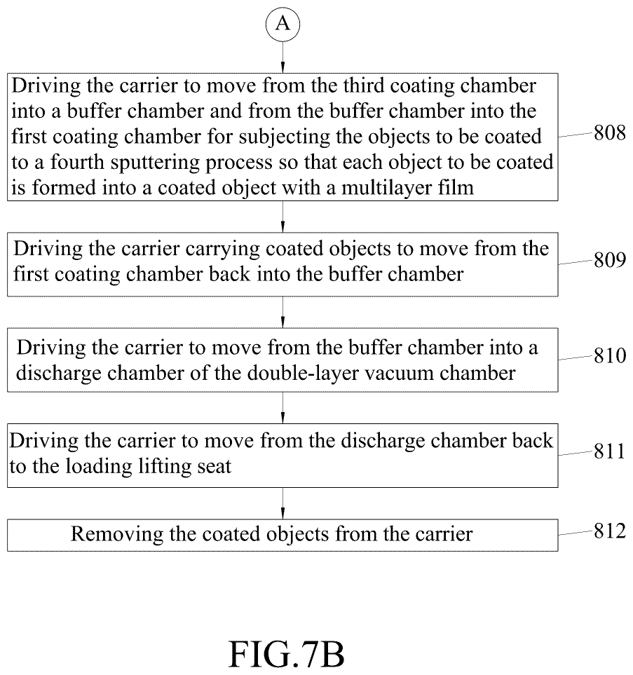

Referring to FIG. 7, a method for coating a multilayer film on the objects to be coated 91 carried by each carrier 9 using the coating apparatus of the first embodiment includes steps 801 to 812. The steps involved in this method will be described in detail below with reference to FIGS. 3, 4 and 8.

In step 801, with reference to FIG. 3, the carrier 9 is placed on the loading lifting seat 221 of the loading and unloading area 2, and the objects to be coated 91 (i.e., packaged finished products) are placed on the carrier 9.

In step 802, the loading lifting seat 221 is driven to rise to the same height as the feed chamber 31 of the double-layer vacuum chamber 3, after which the vacuum valve 71 disposed on the feed chamber 31 is opened, and the loading conveying device 223 is activated to feed the carrier 9 carrying the objects to be coated 91 into the feed chamber 31.

In step 803, as the carrier 9 stays in the feed chamber 31, the heating device 33 is activated to heat and bake the objects to be coated 91 on the carrier 9 for 30 to 480 seconds so as to remove moisture from the objects to be coated 91.

In step 804, with reference to FIG. 4, after heating and baking, the vacuum valve 72 is opened, and the second conveying device 52 in the feed chamber 31 is activated to rotate 90 degrees, after which the first conveying device 51 in the feed chamber 31 is activated to drive the carrier 9 carrying the objects to be coated 91 to move in the Y-direction into the treatment chamber 41. The carrier 9 stays in the treatment chamber 41, and the objects to be coated 91 are subjected to plasma cleaning for 30 to 480 seconds.

In step 805, after the plasma cleaning, the vacuum valve 73 is opened, the second conveying device 52 in the treatment chamber 41 is activated to rotate 90 degrees, after which the first conveying device 51 in the treatment chamber 41 is activated to drive the carrier 9 to move in the X-direction from the treatment chamber 41 into the first coating chamber 42. The carrier 9 stays in the first coating chamber 42, and the objects to be coated 91 are subjected to a first sputtering process for 15 to 90 seconds. It should be noted that this disclosure uses a fixed point coating, that is, during each coating process, the objects to be coated 91 will not move, and they will only move horizontally together with the carrier 9 when the carrier 9 is switched to the next process chamber.

In step 806, after the first sputtering process, the first conveying device 51 in the first coating chamber 42 is activated to drive the carrier 9 to move in the X-direction from the first coating chamber 42 into the second coating chamber 43. The carrier 9 stays in the second coating chamber 43, and the objects to be coated 91 are subjected to a second sputtering process for 120 to 480 seconds.

In step 807, after the second sputtering process, the second conveying device 52 in the second coating chamber 43 is activated to rotate 90 degrees, after which the first conveying device 51 in the second coating chamber 43 is activated to drive the carrier 9 to move in the Y-direction from the second coating chamber 43 into the third coating chamber 44. The carrier 9 stays in the third coating chamber 44, and the objects to be coated 91 are subjected to a third sputtering process for 120 to 480 seconds.

In step 808, after the third sputtering process, the second conveying device 52 in the third coating chamber 44 is activated to rotate 90 degrees, after which the first conveying device 51 in the third coating chamber 44 is activated to drive the carrier 9 to move in the X-direction from the third coating chamber 44 into the buffer chamber 45. The feed lifting seat 61 is then used to drive the carrier 9 from the buffer chamber 45 into the first coating chamber 42. As the carrier 9 stays in the first coating chamber 42, the objects to be coated 91 are subjected to a fourth sputtering process for 60 to 120 seconds. Through this, each object to be coated 91 is formed into a coated object 91′ with a multilayer film (not shown). The layer structure of the multilayer film is stainless steel-copper-copper-stainless steel, and the thickness of each layer is 0.03 to 0.1 μm, 1.5 to 3.5 μm, 1.5 to 3.5 μm, and 0.3 to 0.8 μm, respectively. This kind of layer structure can be used as an electromagnetic shielding film that can prevent electromagnetic interference (EMI). The thickness of each layer of the multilayer film is proportional to the time that the objects to be coated 91 stayed in each process chamber.

In step 809, after the fourth sputtering process, the first conveying device 51 in the first coating chamber 42 is activated to drive the carrier 9 carrying the coated objects 91′ to move in the Y-direction from the first coating chamber 42 back to the feed lifting seat 61 of the buffer chamber 45.

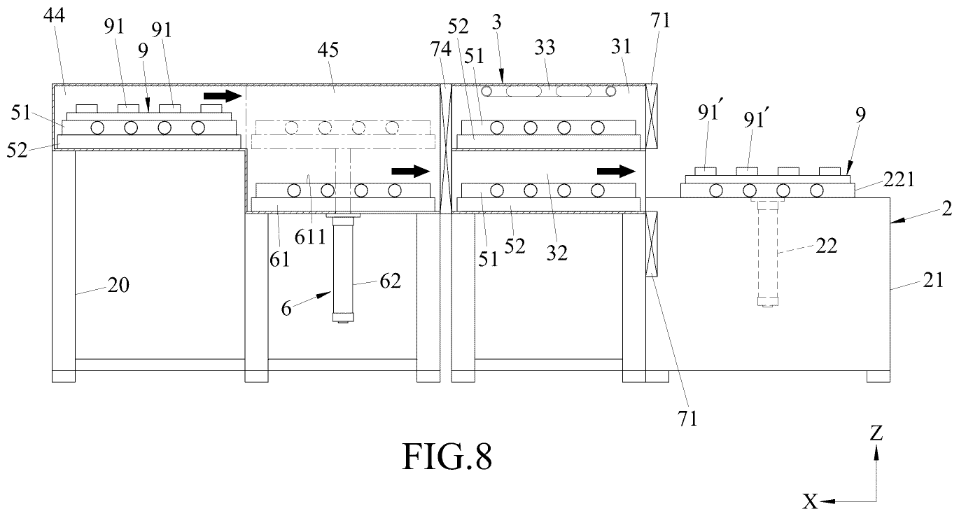

In step 810, with reference to FIG. 8, the feed lifting seat 61 is activated to descend so as to lower the carrier 9 to a position equal to that of the discharge chamber 32 of the double-layer vacuum chamber 3, after which the vacuum valve 74 is opened, the second transfer device 612 is activated to rotate 90 degrees, and the first transfer device 611 is activated to drive the carrier 9 carrying the coated objects 91′ to move in the X-direction from the buffer chamber into the discharge chamber 32.

In step 811, the vacuum valve 71 disposed on the discharge chamber 32 is opened, and the first conveying device 51 in the discharge chamber 32 is activated to drive the carrier 9 carrying the coated objects 91 to move out of the discharge chamber 32 back to the loading lifting seat 221. It should be noted that the vacuum valve 71 of the first embodiment adopts a vertical movable valve that can be moved in the Z-direction to open and close. However, the other vacuum valves of the first embodiment may also adopt this type of vertical movable valve.

In step 812, the coated objects 91′ are removed from the carrier 9.

Although only one carrier 9 is described above, in actual practice, the carriers 9 may be fed into the coating apparatus of this disclosure in a continuous intermittent manner according to the time of entry and exit of each carrier 9 into and from each process chamber. By repeating steps 801 to 811 for each carrier 9, an automated coating production can be achieved. Further, each carrier 9 can be reused. Of course, the loading lifting mechanism 22 may be omitted in this disclosure, in this case, a robotic arm or a human hand may be used to place or remove the carriers 9 into or from the double-layer vacuum chamber 3, the effect of reusing the carriers 9 may be similarly achieved.

It should be noted that, during the fixed point coating process, the carrier 9 is always maintained at the same height, and after the coating process is completed, only then will the carrier 9 be lowered to a position equal to the height of the discharge chamber 32 of the double-layer vacuum chamber 3. It can be understood that, in other variations, the positions of the feed chamber 31 and the discharge chamber 32 may be interchanged such that the discharge chamber 32 is disposed above the feed chamber 31, and the heights of the process chambers may be adjusted and lowered accordingly. Similarly, the carrier 9 can be maintained at the same height during the fixed point coating process, the carrier 9 can be fed from the feed chamber 31 and discharged from the discharge chamber 32.

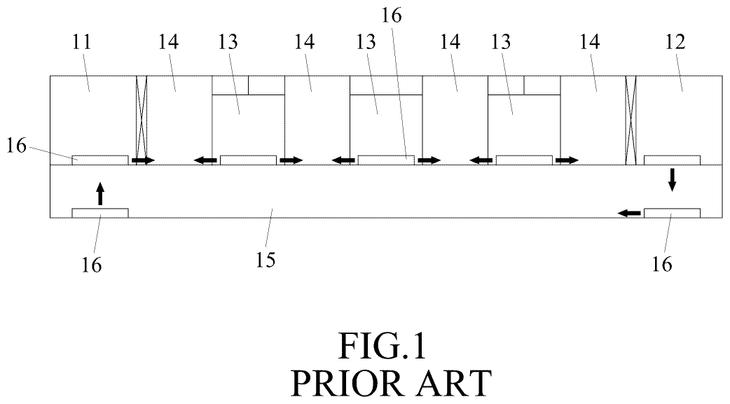

From the aforesaid description, it is apparent that each carrier 9 can selectively enter and exit the same buffer chamber 45 or flexibly travel back and forth to the first coating chamber 42 for coating according to the operating time of each process chamber or coating requirements. Compared with the existing continuous coating production line requiring many carriers 16 (see FIG. 1), this disclosure can reduce the number of the process chambers, so the number of the carriers 9 and their corresponding fixtures (not shown) can also be reduced. Further, the waiting time of each process chamber can be shortened, utilization thereof can be improved, and the operating costs can be saved.

Through the double-layer design of the double-layer vacuum chamber 3 of this disclosure to achieve an upper feed chamber 31 and a lower discharge chamber 32, the conveying distance of each carrier 9 from the discharge chamber 32 to the feed chamber 31 can be shortened, jamming of the incoming and outgoing materials can be prevented so as to shorten the production cycle, increase the production capacity, and reduce the number of the carriers 9. In addition, with the double-layer vacuum chamber 3 and the process chambers 41 to being arranged in two juxtaposed rows, the length of the coating apparatus of this disclosure in the X-direction is shortened, thereby reducing the area occupied by the coating apparatus of this disclosure.

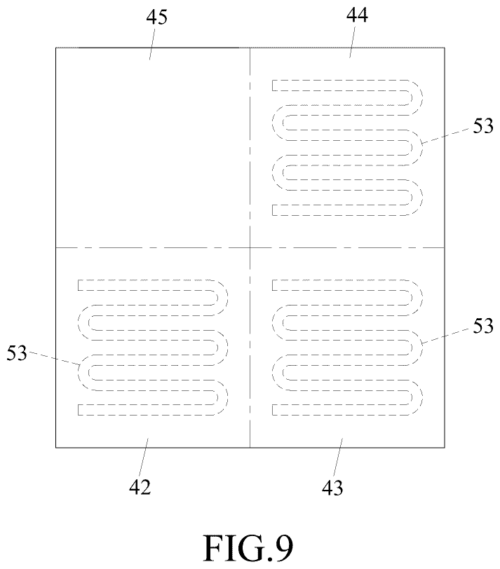

Referring to FIG. 9, it should be noted that, since this disclosure uses a fixed point coating process, the objects to be coated 91 (see FIG. 8) will not move during each coating process, and in order to avoid damage to the objects to be coated 91 by high heat accumulated over a long period of coating time, a cooling device 53 is thus provided in each of the first to third coating chambers 42 to 44. The cooling device 53 is a cooling channel or an opening for passage of a cooling medium, such as, but not limited to, cold water, ethylene glycol, a fluorine cooling liquid or an inert gas such as argon. Through this, the temperatures of each carrier 9 (see FIG. 8) and the objects to be coated 91 can be lowered, so that damage to the objects to be coated 91 due to high temperature during coating can be prevented.

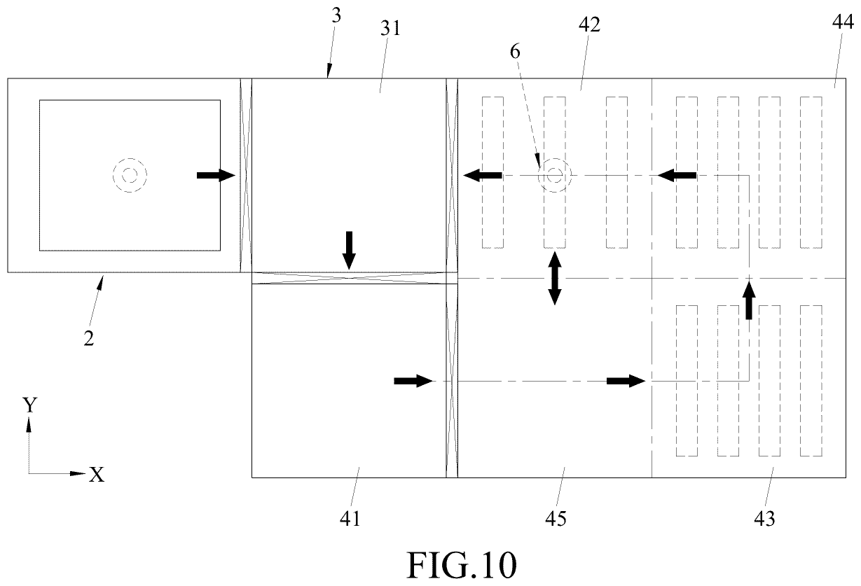

Referring to FIG. 10, in an alternative, the positions of the first coating chamber 42 and the buffer chamber 45 are interchanged, and the feed lifting mechanism 6 is disposed in the first coating chamber 42. The carrier 9 (see FIG. 8) is similarly fed from the feed chamber 31 of the double-layer vacuum chamber 3, passes through the treatment chamber 41 and the buffer chamber 45, and then enter the first coating chamber 42 for the first sputtering process of the objects to be coated 91 (see FIG. 8). Next, the carrier 9 is moved back to the buffer chamber 45, and then sequentially passes through the second coating chamber 43, the third coating chamber 44 and the first coating chamber 42 for the second to fourth sputtering processes of the objects to be coated 91. After the fourth sputtering process, the carrier 9 together with the coated objects 91′ (see FIG. 8) is lowered in the first coating chamber 42, enters the discharge chamber 32 (see FIG. 8) of the double-layer vacuum chamber 3, and is then discharged therefrom.

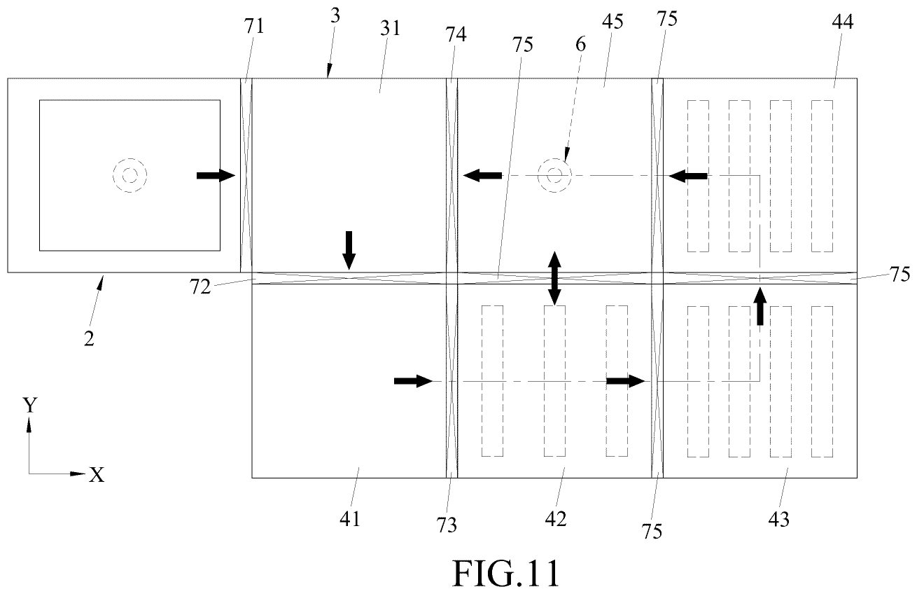

Referring to FIG. 11, in another alternative, four vacuum valves 75 are disposed among the first to third coating chambers 42 to 44 and the buffer chamber 45 to form four independent process chambers with the degree of vacuum thereof being independently controlled to meet operational requirements, such as the resistance value of the coating, microstructure, adhesion, film stress, etc. This disclosure can flexibly configure the vacuum valves 75 to achieve the effect of raising or lowering pressure so as to quickly meet the vacuum degree requirement of the process.

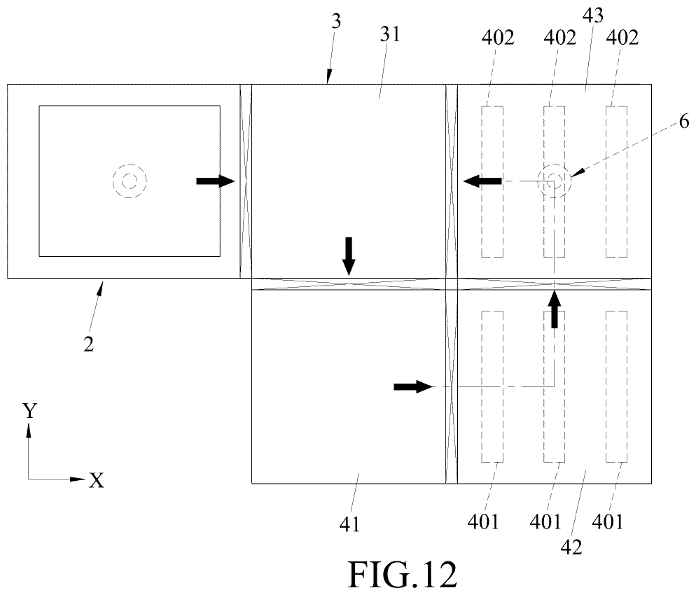

Referring to FIG. 12, a parallel-type coating apparatus according to the second embodiment of the present disclosure is shown to be identical to the first embodiment, but differs in that, the coating apparatus of the second embodiment only includes three process chambers that are independent of each other. The process chambers include the treatment chamber 41 connected to the double-layer vacuum chamber 3, the first coating chamber 42 connected to the treatment chamber 41, and the second coating chamber 43 connected to the first coating chamber 42 and the double-layer vacuum chamber 3.

A plurality of titanium (Ti) targets 401 are disposed in the first coating chamber 42, while a plurality of copper (Cu) targets 402 are disposed in the second coating chamber 43. The feed lifting mechanism 6 is disposed in the second coating chamber 43. Through this, the second embodiment can achieve the purpose of sputtering a titanium-copper (Ti-Cu) multilayer film on each object to be coated 91 and apply it to a redistribution layer (RDL) of a coreless substrate.

As can be seen from the above various embodiments and modified examples, each process chamber can be an independent vacuum chamber or share a same vacuum chamber, and according to the coating requirements, pre-treatment or installation of the targets 401, 402 of different materials and quantities can be selectively conducted in each process chamber, so that different number of layers and thicknesses of films can be coated on various objects to be coated 91 (see FIG. 8).

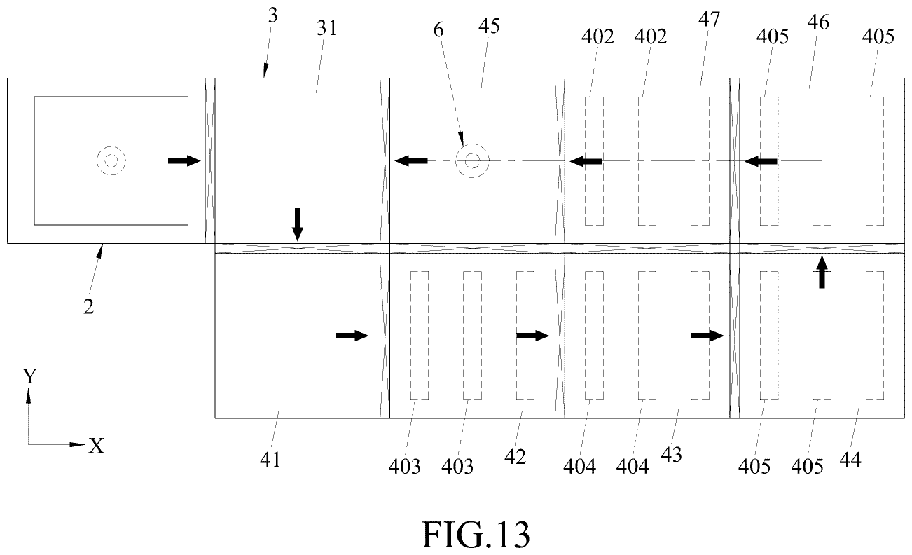

Referring to FIG. 13, a parallel-type coating apparatus according to the third embodiment of the present disclosure is shown to be identical to the second embodiment, but differs in that, the coating apparatus of the third embodiment includes seven process chambers that are independent of each other. The process chambers include the treatment chamber 41 connected to the double-layer vacuum chamber 3, the first coating chamber 42 connected to the treatment chamber 41, the second coating chamber 43 connected to the first coating chamber 42, the third coating chamber 44 connected to the second coating chamber 43, a fourth coating chamber 46 connected to the third coating chamber 44, a fifth coating chamber 47 connected to the second and fourth coating chambers 43, 46, and the buffer chamber 45 connected to the first coating chamber 42, the fifth coating chamber 47 and the double-layer vacuum chamber 3. The first to fifth coating chambers 42, 43, 44, 46, 47 are respectively provided with a plurality of aluminum (Al) targets 403, a plurality of titanium (Ti) targets 404, a plurality of nickel vanadium (NiV) targets 405, a plurality of nickel vanadium (NiV) targets 405, and a plurality of copper (Cu) targets 402. The feed lifting mechanism 6 is disposed in the buffer chamber 45. Through this, the third embodiment can achieve the purpose of sputtering an aluminum-titanium-nickel vanadium-nickel vanadium-copper (Al-Ti-NiV-NiV-Cu) multilayer film on each object to be coated 91.

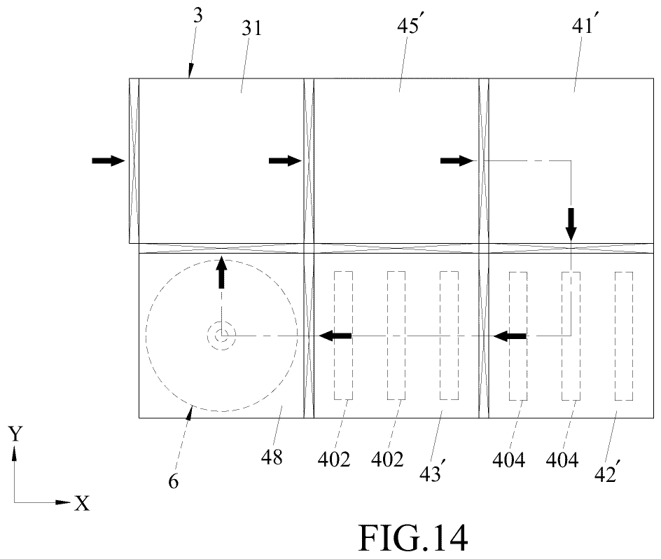

Referring to FIG. 14, a parallel-type coating apparatus according to the fourth embodiment of the present disclosure is shown to be identical to the second embodiment, but differs in that, the coating apparatus of the fourth embodiment includes five process chambers. The process chambers include the buffer chamber 45′ connected to the double-layer vacuum chamber 3 in the X-direction, the treatment chamber 41′ connected to the buffer chamber 45′ in the X-direction, the first coating chamber 42′ connected to the treatment chamber 41′ in the Y-direction, the second coating chamber 43′ connected to the first coating chamber 42′ in the X-direction, and a conveying chamber 48 connected to the second coating chamber 43′ and the double-layer vacuum chamber 3.

The loading and unloading area 2 (see FIG. 12) is omitted in this embodiment, and a robotic arm (not shown) or a human hand is used to remove each carrier 9 (see FIG. 8) from the discharge chamber 32 (see FIG. 8) and place it into the feed chamber 31 (see FIG. 8) of the double-layer vacuum chamber 3. The effect of repeatedly using the carriers 9 can also be achieved.

A plurality of titanium (Ti) targets 404 are disposed in the first coating chamber 42′, and a plurality of copper (Cu) targets 402 are disposed in the second coating chamber 43′. The feed lifting mechanism 6 is disposed in the conveying chamber 48.

In this embodiment, the carrier 9 is fed into the feed chamber 31 of the double-layer vacuum chamber 3, passes through the buffer chamber 45′, and enters the treatment chamber 41′ for subjecting the objects to be coated 91 (see FIG. 8) carried by the carrier 9 (see FIG. 8) to plasma cleaning. Next, after the plasma cleaning, the carrier 9 enters the first coating chamber 42′ for subjecting the objects to be coated 91 to a first sputtering process, and then enters the second coating chamber 43′ for subjecting the objects to be coated 91 to a second sputtering process. Finally, the carrier 9 enters the conveying chamber 48, is lowered through the feed lifting mechanism 6, enters the discharge chamber 32 (see FIG. 8) of the double-layer vacuum chamber 3, and is then discharged therefrom. Through this, the fourth embodiment can achieve the purpose of sputtering a titanium-copper (Ti-Cu) multilayer film on each object to be coated 91. For the objects to be coated 91 that require high electrical properties, such as contact resistance, the vacuum degree of the buffer chamber 45′ is increased so as to reduce the outgassing rate of the objects to be coated 91 and to help improve the cleanliness of the surfaces (for example, metal pads) of the objects to be coated 91.

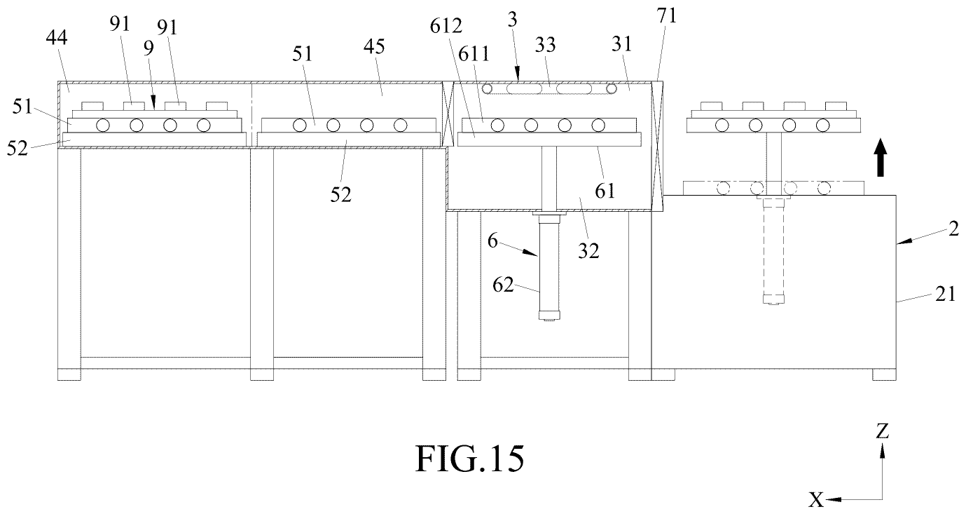

It should be noted that the feed lifting mechanism 6 of the embodiments described above is disposed in the last process chamber, so that each embodiment has the advantage of reducing the vacuuming time for feeding and discharging, and has a simple mechanism configuration. However, in some embodiments, the feed lifting mechanism 6 may be disposed in the double-layer vacuum chamber 3. In this case, as shown in FIG. 15, the partition plate 34 (see FIG. 3) is omitted, and through the feed lifting seat 61 of the feed lifting mechanism 6 that can be raised and lowered in the double-layer vacuum chamber 3 and that has substantially the same function as the feed chamber 31 and the discharge chamber 32, the purpose of feeding at the upper layer and discharging at the lower layer can also be achieved. When each object to be coated 91 is only a substrate or a wafer mounted on an iron frame, the robotic arm can be used to extend in to the double-layer vacuum chamber 3 to pick up and place the objects to be coated 91 on each carrier 9. There is no need to remove each carrier 9 from the apparatus, so that each carrier 9 can be circulated and reused. When it is time for maintenance of the apparatus, only then is each carrier 9 removed for cleaning. Further, in this case, steps 801 and 802 of the method of this disclosure can be omitted.

In summary, in the parallel-type coating apparatus of this disclosure, through the double-layer design of the double-layer vacuum chamber 3, the purpose of feeding and discharging materials (objects to be coated 91) from the upper and lower layers can be realized, so that the conveying distance of each carrier 9 from the discharge chamber 32 back to the feed chamber 31 can be shortened, the production cycle can also be shortened, the production capacity can be increased, and the number of the carrier 9 can be reduced. Further, with the double-layer vacuum chamber 3 and the process chambers being arranged in two juxtaposed rows in the Y-direction, the length of the coating apparatus of this disclosure in the X-direction can be shortened to thereby reduce the area occupied by the coating apparatus of this disclosure, and each carrier 9 can selectively go back and forth to the same process chamber, so the number of the process chambers and the carriers 9 can be reduced, the waiting time of each process chamber can be shortened, and the utilization rate can be improved. Therefore, the object of this disclosure can indeed be achieved.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A parallel-type coating apparatus suitable for coating at least one object to be coated carried by a carrier, comprising:
a double-layer vacuum chamber including a feed chamber and a discharge chamber opposite to each other in a Z-direction, said feed chamber being configured for feeding the carrier, said discharge chamber being configured for discharging the carrier;
a plurality of process chambers for performing at least a fixed point coating on the at least one object to be coated, two of said process chambers being immediately adjacent to said double-layer vacuum chamber, said double-layer vacuum chamber and said process chambers being arranged in two juxtaposed rows in a Y-direction transverse to the Z-direction;
a feed lifting mechanism disposed in one of said double-layer vacuum chamber 3 and said process chambers, and including a feed lifting seat for carrying the carrier, said feed lifting seat being movable in the Z-direction, and including a first transfer device for conveying the carrier to move in an X-direction transverse to the Y-direction and the Z-direction, and a second transfer device for conveying the carrier to move in the Y-direction; and
a plurality of first conveying devices respectively disposed in the other ones of said process chambers for conveying the carrier to move in the X-direction or Y-direction.

2. The parallel-type coating apparatus as claimed in claim 1, further comprising a plurality of second conveying devices respectively located on bottom sides of said first conveying devices for respectively driving said first conveying devices to rotate 90 degrees.

3. The parallel-type coating apparatus as claimed in claim 2, further comprising a loading and unloading area immediately adjacent to said double-layer vacuum chamber, said loading and unloading area including a loading lifting seat movable in the Z-direction, said loading lifting seat being configured for placement of the carrier thereon, and having a loading conveying device for conveying the carrier to move in the X-direction.

4. The parallel-type coating apparatus as claimed in claim 1, wherein said double-layer vacuum chamber further includes a heating device disposed in said feed chamber for heating and baking the at least one object to be coated.

5. The parallel-type coating apparatus as claimed in claim 1, wherein said process chambers include a treatment chamber connected to said double-layer vacuum chamber, a first coating chamber connected to said treatment chamber, a second coating chamber connected to said first coating chamber, a third coating chamber connected to said second coating chamber, and a buffer chamber connected to said first coating chamber, said third coating chamber and said double-layer vacuum chamber, and wherein each of said buffer chamber, said first coating chamber, said second coating chamber and said third coating chamber has a vacuum degree not lower than that of said treatment chamber.

6. The parallel-type coating apparatus as claimed in claim 5, wherein said first coating chamber, said second coating chamber, said third coating chamber and said buffer chamber communicate with each other and have the same vacuum degree.

7. The parallel-type coating apparatus as claimed in claim 5, wherein each of said first coating chamber, said second coating chamber and said third coating chamber has at least one target.

8. The parallel-type coating apparatus as claimed in claim 7, wherein said at least one target is cylindrical.

9. The parallel-type coating apparatus as claimed in claim 5, wherein said first coating chamber, said second coating chamber, said third coating chamber and said buffer chamber are independent vacuum chambers.

10. The parallel-type coating apparatus as claimed in claim 5, wherein a vacuum valve is disposed between said double-layer vacuum chamber and said treatment chamber, between said treatment chamber and said first coating chamber, and between said buffer chamber and said double-layer vacuum chamber, and wherein said vacuum valve is movable in the Z-direction to open or close.

11. The parallel-type coating apparatus as claimed in claim 5, wherein said feed lifting mechanism is disposed in said buffer chamber.

12. The parallel-type coating apparatus as claimed in claim 1, wherein said process chambers include a treatment chamber connected to said double-layer vacuum chamber, a first coating chamber connected to said treatment chamber, a second coating chamber connected to said first coating chamber, a third coating chamber connected to said second coating chamber, a fourth coating chamber connected to said third coating chamber, a fifth coating chamber connected to said second coating chamber and said fourth coating chamber, and a buffer chamber connected to said first coating chamber, said fifth coating chamber and said double-layer vacuum chamber.

13. The parallel-type coating apparatus as claimed in claim 12, wherein said first coating chamber, said second coating chamber, said third coating chamber, said fourth coating chamber, said fifth coating chamber and said buffer chamber are independent vacuum chambers, and wherein each of said first coating chamber, said second coating chamber, said third coating chamber, said fourth coating chamber and said fifth coating chamber has at least one target.

14. The parallel-type coating apparatus as claimed in claim 1, further comprising a cooling device provided in each of said process chambers.

15. A method for coating a multilayer film on at least one object to be coated carried by a carrier, comprising:
(A) feeding the carrier carrying the at least one object to be coated into a feed chamber of a double-layer vacuum chamber;
(B) driving the carrier to pass through a plurality of process chambers arranged in two juxtaposed rows so as to form the at least one object to be coated into at least one coated object with a multilayer film; and
(C) driving the carrier together with the at least one coated object to discharge from a discharge chamber of the double-layer vacuum chamber which is opposite to the feed chamber in a Z-direction.

16. The method as claimed in in claim 15, wherein a step of placing the carrier on a loading lifting seat of a loading and unloading area immediately adjacent to the double-layer vacuum chamber is performed before step (A), the loading lifting seat being activated to feed the carrier into the feed chamber.

17. The method as claimed in in claim 15, wherein, in step (B), the carrier is driven to selectively enter and exit one of the process chambers.

18. The method as claimed in in claim 15, wherein each of the process chambers has a cooling device.
